(19) United States
(12) Patent Application Publication
(10) Pub. No.: US 2013/0009669 A1
(43) Pub. Date: Jan. 10, 2013

(54) Voltage Mode Driver

(75) Inventor: Venkata N.S.N. Rao, Santa Clara, CA (US)

(73) Assignee: KOOL CHIP, INC., San Jose, CA (US)

(21) Appl. No.: 13/225,381

(22) Filed: Sep. 2, 2011

Related U.S. Application Data
(60) Provisional application No. 61/379,717, filed on Sep. 2, 2010.

(51) Int. Cl. H03K 3/00

(52) U.S. Cl. 327/108

(57) ABSTRACT

A differential mode driver for driving a differential signal, comprises, at least one unit cell, wherein each of the at least one unit cell comprises at least one resistor and at least one switch resistance and wherein the ratio of the resistances of the at least one resistor and the at least one switch resistance is greater than or equal to a predefined ratio.

### FIELD OF INVENTION

This invention generally relates to a differential driver, and, in particular, to a push-pull voltage mode driver that supports n-taps and low power swing operation.

### BACKGROUND

In high speed data transmission systems, a transmitter consumes the most power in such systems. For low power applications, it is important to reduce this power consumption of the transmitter. One method that has been used is to reduce the operating voltage for the transmitter to reduce the overall power consumption. However, this does not aid in power reduction at a final stage driver, where, conventionally, current differential drivers are used because of their low susceptibility to the power supply noise. For example, a typical 1 volt, 50 ohms differential driver with a termination of 100 ohms can consume around 20 mA, a relatively large amount of current. Furthermore, supporting multiple taps can lead to even more power usage.

A voltage mode driver can be used instead of a differential driver, where the voltage mode driver may only consume 5 mA to achieve the same driver characteristics. However, typical voltage mode drivers consume more current in pre- and de-emphasis modes and are difficult to incorporate for a pre-defined number of taps. Therefore, it is desirable to provide new voltage mode drivers that allow for constant compensated impedance, e.g., process, voltage and temperature (“PVT”), in an n-tap operation and consumes less current in an n−1 tap operation. It is also desirable to provide new voltage mode drivers for an n+1 tap operation (including tri-state) with minimal skew impact.

Another issue is noise coupling from an adjacent channel, which causes quite a bit of distortion at the receiving end of the channel. Various methods can be used to take care of noise at the design phase. However, effective techniques are not available once the design is done. Therefore, it is desirable to provide new methods and circuits for noise cancellation.

### SUMMARY OF INVENTION

An object of this invention is to provide a low power voltage mode driver with multi-tap pre-emphasis and de-emphasis.

Another object of this invention is to provide a voltage mode driver with cross talk cancellation.

Briefly, the present invention discloses a differential mode driver for driving a differential signal, comprising, at least one unit cell, wherein each of the at least one unit cell comprises at least one resistor and at least one switch resistance and wherein the ratio of the resistances of the at least one resistor and the at least one switch resistance is greater than or equal to a predefined ratio.

An advantage of this invention is that a low power voltage mode driver with multi-tap pre-emphasis and de-emphasis is provided.

Another advantage of this invention is that a voltage mode driver with a low power voltage mode driver with cross talk cancellation is provided.

### DESCRIPTION OF THE DRAWINGS

The foregoing and other objects, aspects, and advantages of the invention can be better understood from the following detailed description of the preferred embodiment of the invention when taken in conjunction with the accompanying drawings in which:

FIG. 1 illustrates a block diagram of a voltage mode driver of the present invention.

FIG. 2 illustrates a circuit diagram of a differential-mode output-stage unit cell of the present invention.

FIG. 3 illustrates a circuit diagram of a separate termination implementation of a differential mode output stage unit cell of the present invention.

FIG. 4 illustrates a band gap diagram of a differential mode output stage unit cell of the present invention.

FIG. 5 illustrates an equally weighted driver of the present invention having unit cell blocks.

FIG. 6 illustrates a binary weighted driver of the present invention having unit cell blocks.

FIG. 7 illustrates another binary weighted driver of the present invention using unit cell blocks.

FIG. 8 illustrates yet another binary weighted driver of the present invention using unit cell blocks.

FIG. 9 illustrates a circuit diagram of a typical 50 ohms voltage mode driver.

FIG. 10 illustrates a circuit diagram of a voltage mode driver of the present invention with an impedance of 50 ohms and emphasis of −80 mv.

FIGS. 11a, 11b, and 11c illustrate different slew rate control circuits of the present invention.

FIG. 12 illustrates a circuit diagram of an n-tap enable generation circuit of the present invention.

FIGS. 13a and 13b illustrate graphical representations of noise induced from adjacent switching channels.

FIG. 14 illustrates graphical representations of the results of a noise cancellation method of the present invention to adjust an emphasis setting of a given channel.

FIGS. 15a and 15b illustrate graphical representations of the results of another noise cancellation method of the present invention to adjust an emphasis setting of a given channel.

FIG. 16 illustrates a compensation and data flow diagram for several channels.

### DETAILED DESCRIPTION OF THE PREFERRED EMBODIMENTS

In the following detailed description of the embodiments, reference is made to the accompanying drawings, which form a part hereof, and in which is shown by way of illustration of specific embodiments in which the present invention may be practiced.

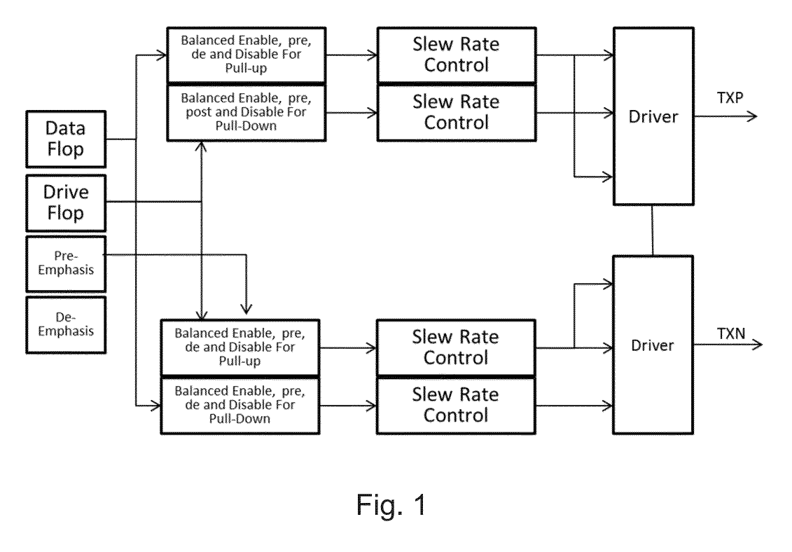

FIG. 1 illustrates a block diagram of a voltage mode driver of the present invention.

Most passive components have little temperature and voltage dependency, whereas active components have a high degree of dependency on the voltage and temperature. The characteristics of devices and linearity of drivers necessitate that the passive components be a greater portion of the total components to reduce the dependency on temperature and voltage for such systems. However, this increases the output capacitance as well as the load on the pre-driver.

A compromise is to use a unit cell circuit for the driver, where the unit's ratio between a resistor and a switch resistance of the unit cell is greater than or equal to 2:1 (or another predefined ratio) in any given corner and temperature. This can be good enough to satisfy the linearity requirement and to impose a small load on the output pad.

Generally, the present invention discloses various differential mode drivers with a high degree of PVT compensation using a low number of bits. The differential mode drivers include using the following techniques: (1) an equal weighted legs technique; (2) two binary weighted legs with a one unit common cell technique; (3) binary weighted legs with a second unit common cell technique; and (4) binary weighted legs with a third type unit cell technique.

Furthermore, low power n-cap capability is achieved using these different techniques by utilizing a variable driver strength and termination between positive and negative terminals of the driver. In addition , other techniques can switch the power supply based on emphasis requirements.

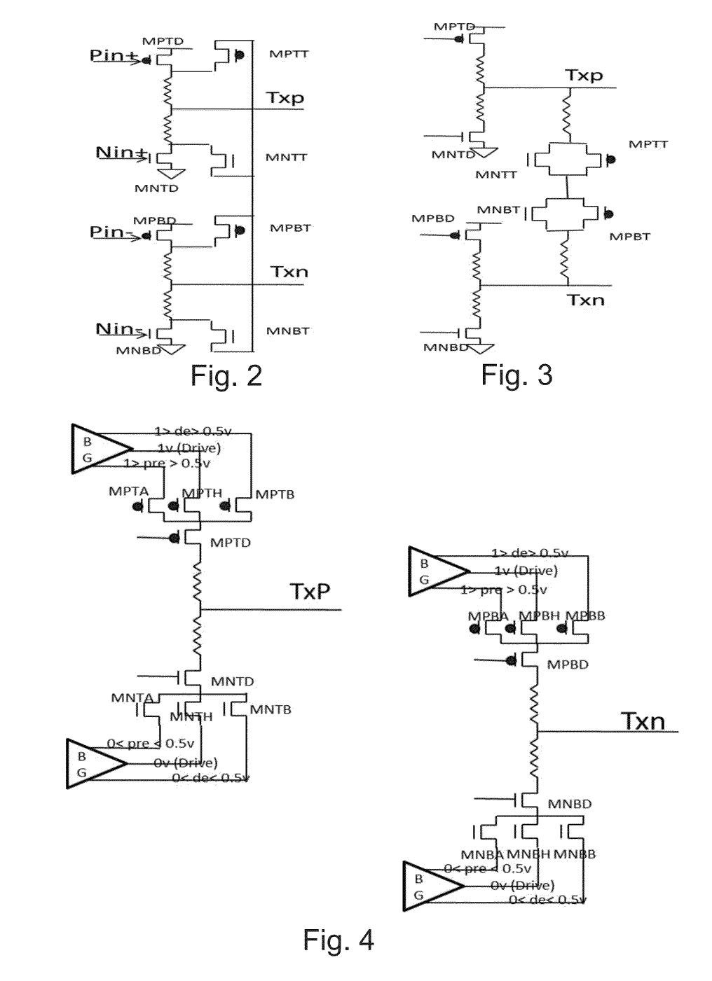

The various differential mode driver cells of the present invention are illustrated in FIGS. 2, 3, and 4 and are optimized using resistors RTT, RTB, RBT, and RBT in a fast corner, switches MPTD, MNTD, MPBD, and MNBD in a slow corner, a lowest voltage, a lowest temperature, and a 2:1 ratio between the resistors and switch resistances. In every possible other corner of the PVT (process, voltage, and temperature), the ratio is larger than 2:1.

FIG. 2, FIG. 3 and FIG. 4 illustrate circuit diagrams of various differential unit driver cells of the present invention, which provide drive with various degrees of emphasis. As shown in the FIG. 2 and FIG. 3, the differential inputs MPTD, MNTD, MPBD, MNBD, MPTT, MNTT, MPBT, and MNBT place the respective unit cell in a drive mode with various degrees of emphasis. Whenever MPTD, MNTD, MNTT, and MNBT=0 and MPBD, MNBD, MPBT, and MPTT=1, then the respective unit cell drives an output of the respective cell to a high signal; reversing the input signals force the output of the respective cell to a low signal. When MNTD, MNBD, MPTT, and MPBT=0 and MPTD, MPBD, MNBT, and MNTT=1, the unit cell is in termination mode. One of the advantages of the invention is the elimination of the need for stacked transistors. The invention also utilizes two resistors and two transistors to eliminate large crow-bar current and slew rate control. This invention also skillfully utilizes the separation required as per the latch-up rules.

Generally, a unit cell illustrated in FIG. 2 has lowest output capacitance due to a shared resistor, whereas a unit cell illustrated in FIG. 3 allows the driver to be constructed using binary weighted legs. The impedance offered by the unit leg depends on the accuracy or granularity requirements. For example, a driver with the worst case granularity of less than or equal to 1% requires 256 unit cells.

A unit cell illustrated in FIG. 4 uses a band gap (“BG”) to generate different stable supplies to emulate pre- and de-emphasis, rather than using a termination method. As shown in this figure, a circuit generates two voltage ranges one from 0v to 0.5v and other from 0.5v to 1.0v in steps of 20 mv. The unit driver cell uses a stack of two transistors: MPTD to put the driver in a pull-up mode; MPTH to drive 1v on to output; MPTA to drive a pre-emphasis voltage; and MPTB to drive a de-emphasis voltage. Similarly, the differential inputs can be used as the following: MNTD to put the driver in pull-down mode; MPTL to drive 0v on to output; MNTA to drive pre-emphasis voltage; and MNTB to drive de-emphasis voltage. This architecture can be extended to create an N-tap driver where N is greater than or equal to 1. The operation and compensation of this unit cell can be similar to other unit cells, but does not require termination, unlike the previous unit cells of the present invention.

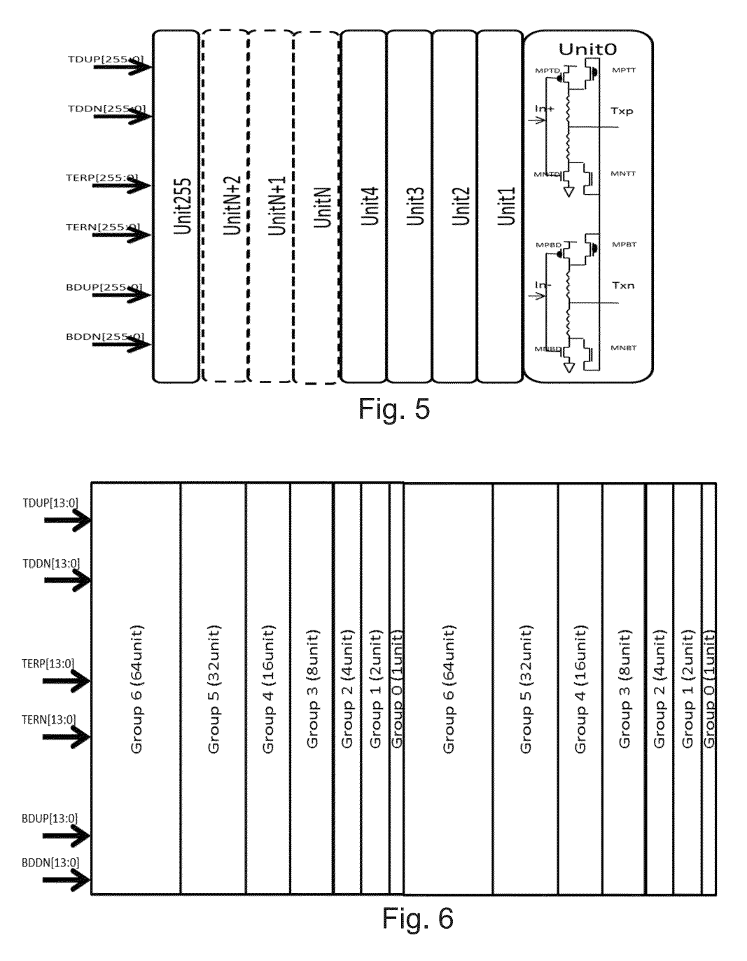

The impedance mismatch between the driver and transmission line can decrease the signal to noise ratio. The mismatch can be minimized by designing a programmable PVT compensated driver. This invention discusses various weighing techniques to create programmable PVT compensated driver using different unit cells. For instance, FIG. 5 illustrates an equally weighted driver of the present invention having unit cell blocks. Here, 256 unit cells (where a single unit cell is illustrated in FIG. 2) are coupled in equal weighted fashion. This reduces the impedance spike at the output if for any reason the driver PVT compensation code changes, but requires 1536 signals to control the driver.

FIG. 6 illustrates a binary weighted driver of the present invention having unit cell blocks. Here, 256 legs are arranged in two binary weighted groups. This reduces the number of the control signal to 96.

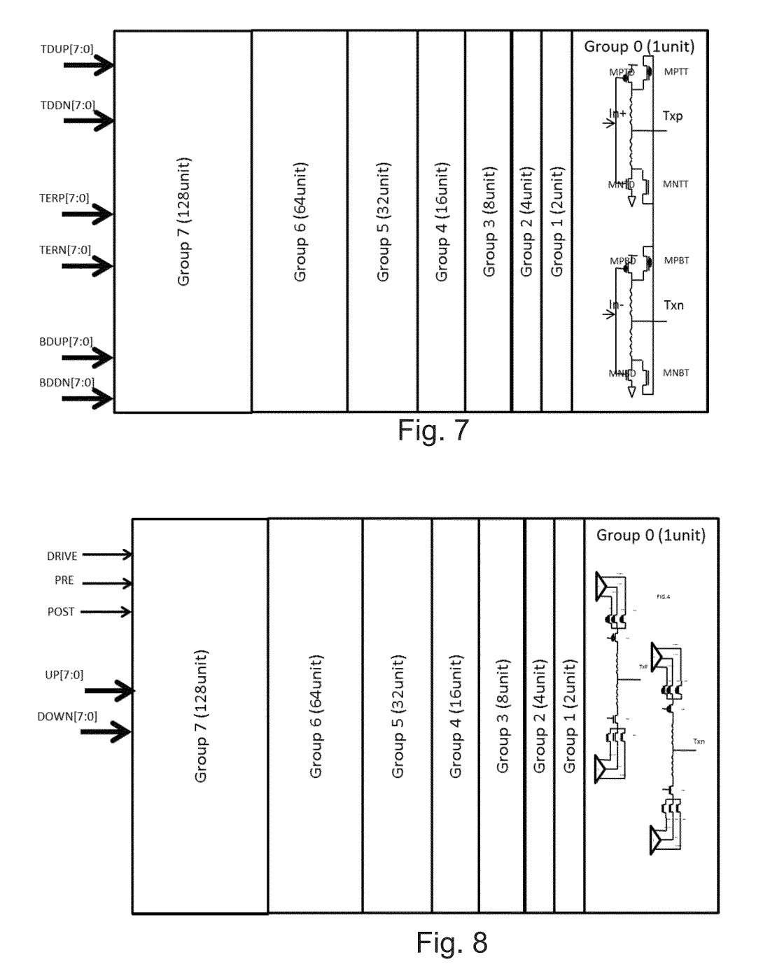

FIG. 7 illustrates another binary weighted driver of the present invention using unit cell blocks. Here, 256 unit cells (where a single unit cell is illustrated in FIG. 3) can be used in one group of binary weighted output stage. This not only brings down the number of the control signals to 48, but also allows the independent control of emphasis and drive. The emphasis portion can be easily detached from emphasis in the application where drive only is required.

FIG. 8 is yet another binary weighted driver of the present invention using unit cell blocks. Here, 256 BG unit cells are coupled in a binary weighted fashion, which requires 50 signals (similar to an implementation of an embodiment of the present invention illustrated in FIG. 7).

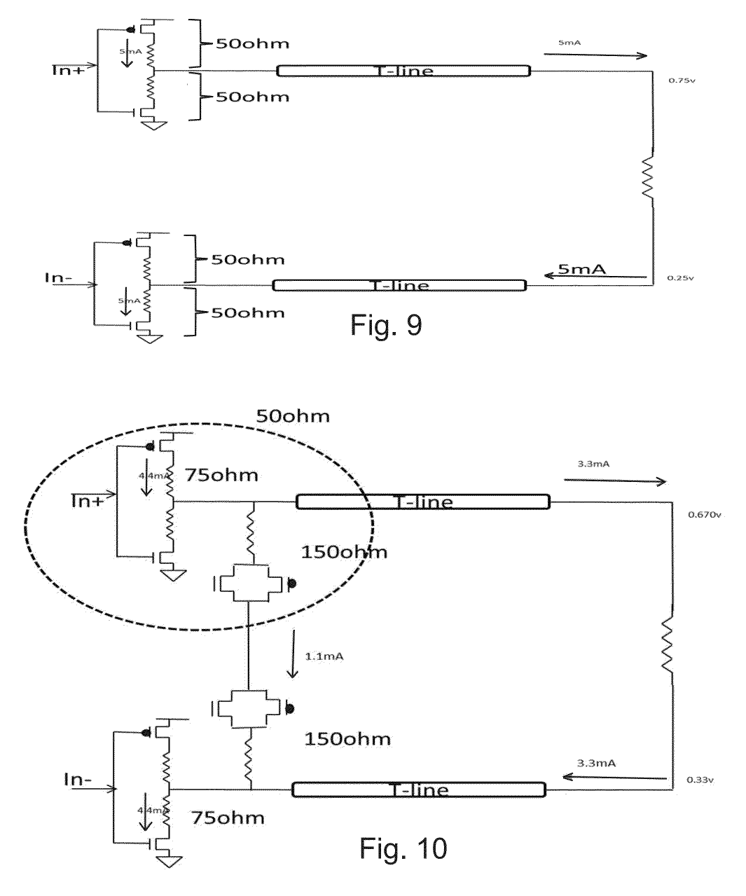

FIG. 9 illustrates a circuit diagram of a typical 50 ohms voltage mode driver. A 1v, 50 ohm voltage mode driver with 128 legs on in drive mode can consume around 5 mA. Thus, every leg offers an impedance of around 6.4K ohms or consumes 39 micro amps.

FIG. 10 illustrates a circuit diagram of a voltage mode driver of the present invention with an impedance of 50 ohms and emphasis of −80 mv. The pre/de-emphasis of 80 mv requires a drive of 75 ohms and a termination of 150 ohms. This requires a driver to shut off 43 legs and a termination on 43 legs. This can simplify the emphasis design to a large extent. Furthermore, the current through the driver decreases from 5 mA to 4.3 mA which reduces the overall transmitter power.

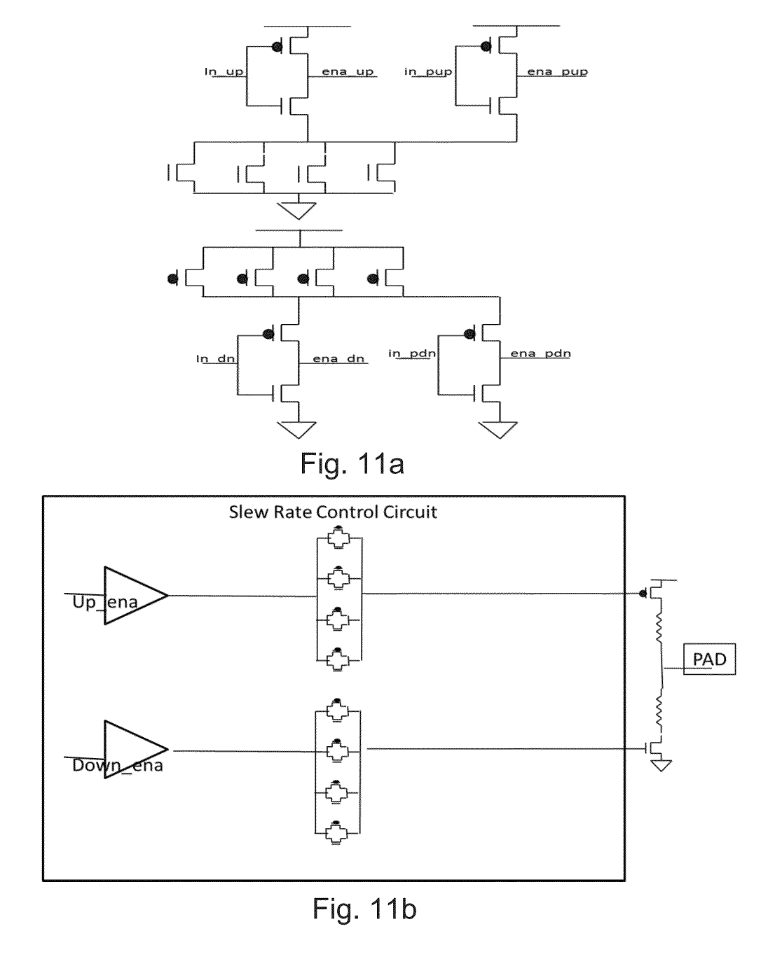

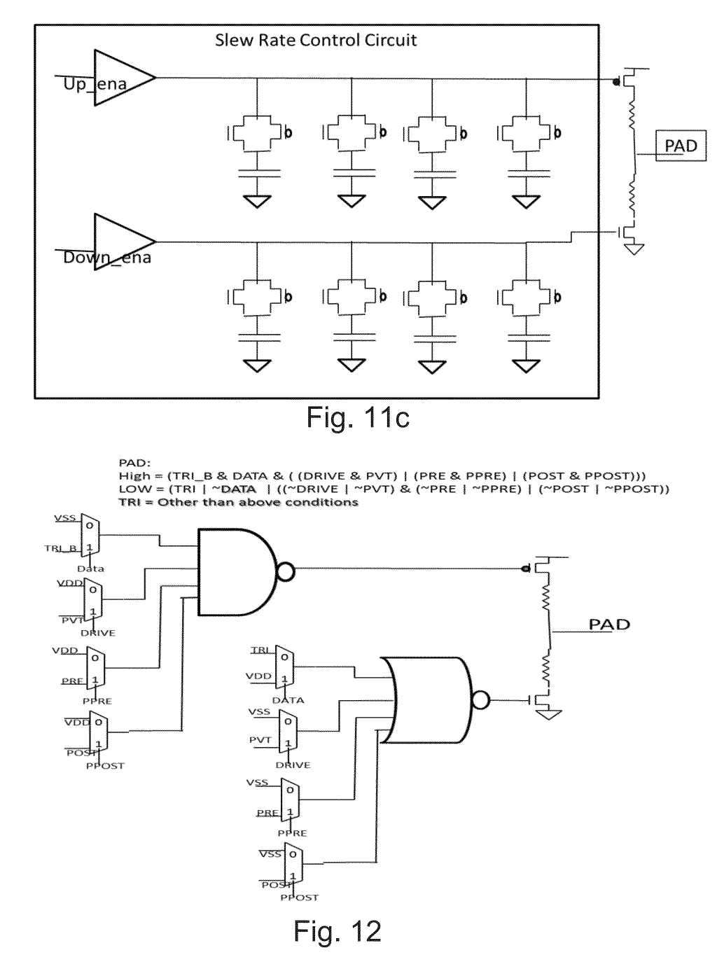

FIGS. 11a, 11b, and 11c illustrate different slew rate control circuits of the present invention. The first slew rate control circuit illustrated in FIG. 11a controls the slew rate by changing a rise or fall path resistance. The second slew rate control circuit illustrated in FIG. 11b changes resistance in both the rise and fall paths. The third slew rate control circuit illustrated in FIG. 11c changes capacitance in the rise and fall paths. Since the design of a base leg for slew rate control is the same as a driver, a similar technique can be used in slew rate design. In addition, the ratio between resistor and top switch can be changed from 2:1 to 4:1. This can make it less dependent on temperature and voltage and does not require expensive compensation techniques.

FIG. 12 illustrates a circuit diagram of an n-tap enable generation circuit of the present invention. The circuit illustrates a method to design an N-tap driver with a very few number of flops and circuitry. The number of flops required is equal to N+1, where N is a number of taps and a number of MUX's required is equal to N+1, where an additional 1 forces the driver to a tri-state. As described in the equations in FIG. 12, the circuit drives low on to pull-up if the driver is not tri-stated, i.e., data is high and pvt or pre or post is enabled. Similarly the circuit drives high on to pull-down if the driver is not tri-stated, pvt or pre or post is enabled, and the data is low. In all other cases, the driver is drive high on to pull-up, and slow on to pull-down. This circuit gives equal delay from data, pre and de-emphasis flops to the input of final driver with fewer gates.

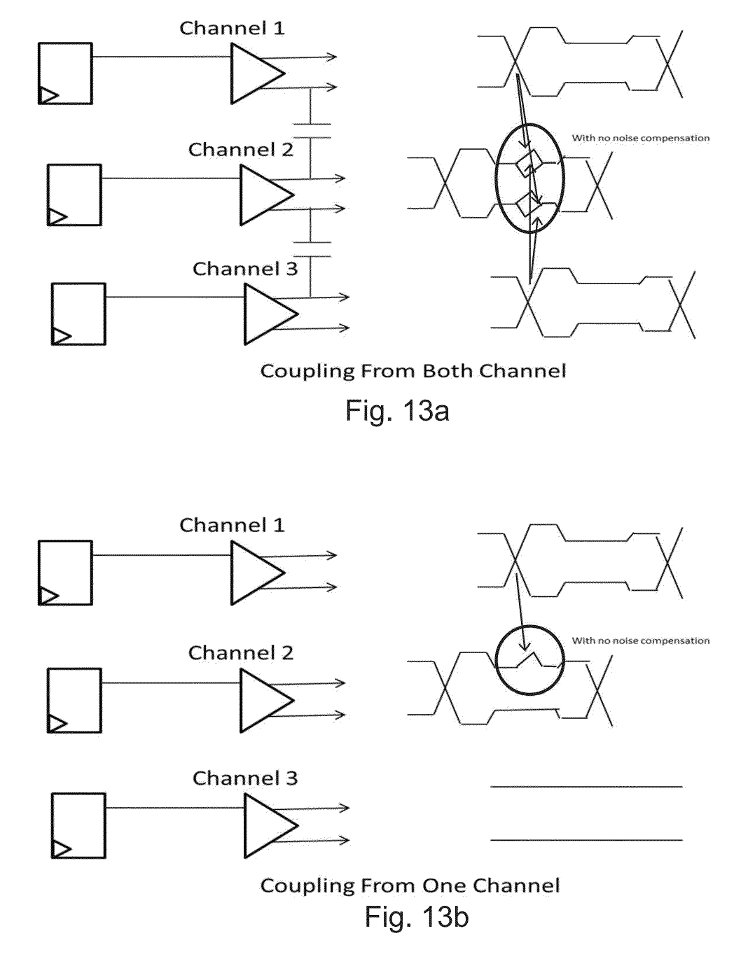

FIGS. 13a and 13b illustrate graphical representations of noise induced from adjacent switching channels. Switching channels can induce a glitch on a stationary channel or can cause the cross over to push out. The direction and magnitude of the glitch depends on an aggressor slew rate, a coupling to channel capacitance ratio, and a victim driver impedance. Once the channel is designed, it can be very difficult to use static techniques to compensate for the noise since it is data dependent. Compensation techniques would need to know the data on the adjacent channel and a magnitude of the compensation required. That means compensation logic should be able to read the aggressor data and adjust the amount and direction of compensation.

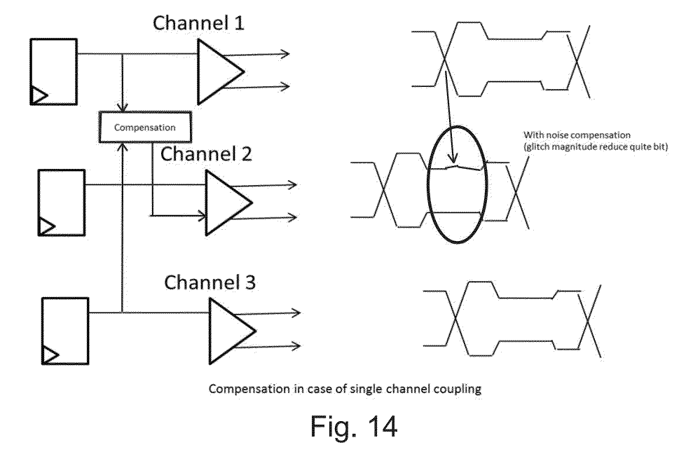

FIG. 14 illustrates graphical representations of the results of a noise cancellation method of the present invention to adjust an emphasis setting of a given channel. Since the data pattern is known in advance and a driver of the present invention supports n-taps with little design change, noise cancellation can be performed. Based on channel characteristics, user programs the amount and direction of coupling required into a compensation block. For example, Channel 1: TXN couples to Channel 2: TXP. If Channel 2 is stationary and Channel 1 is driven high, this would introduce a negative glitch of M-mv. Similarly a low driving Channel 1 would introduce a positive glitch. In this case, a user programs the direction as negative and magnitude of compensation as M-mv, or removes N-compensation legs and adds N-emphasis legs. This would ensure constant impedance of the driver and compensates for the glitch.

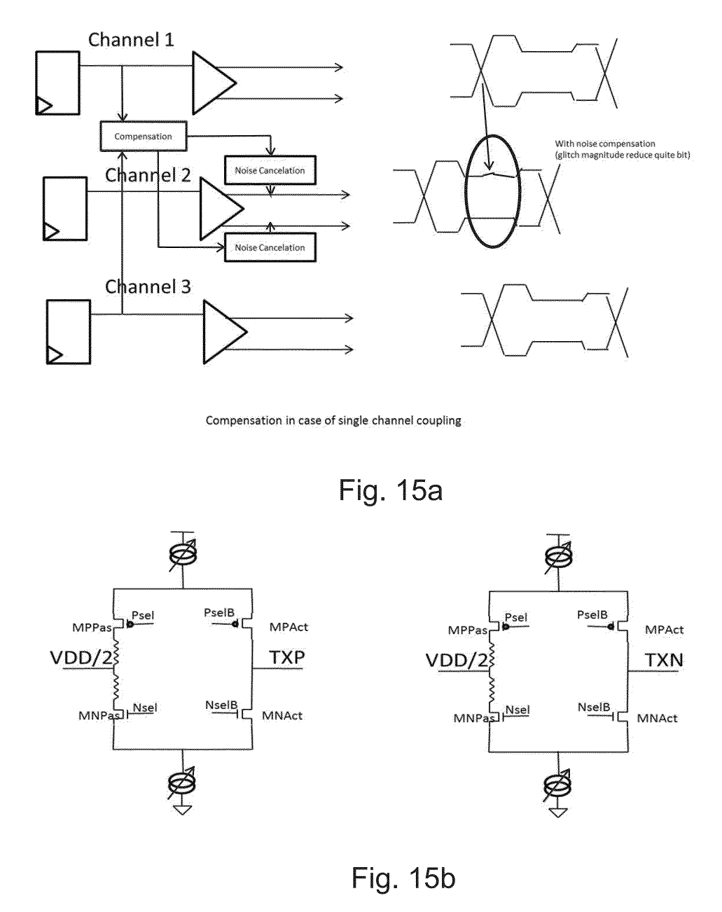

Alternate noise compensation (NC) methods can also be done without changing the driver compensation legs as illustrated in FIGS. 15a and 15b. FIGS. 15a and 15b illustrate graphical representations of the results of another noise cancellation method of the present invention to adjust an emphasis setting of a given channel. First, a user can program the amount of compensation required for high and low signals by changing the current sources settings. When no compensation is required on pull-up, NC forces 0 onto Pse1 and 1 onto Pse1B; and similarly 1 onto Nse1 and 0 onto Nse1B.

NC continuously monitors the data on adjacent channels and enables the appropriate Pse1/Pse1B or Nse1/Nse1B signals. This method would not require any changes to the normal driver operation and ensure required pre-defined impedance at the output. It would also keep the current sources in saturation by using differential current sources.

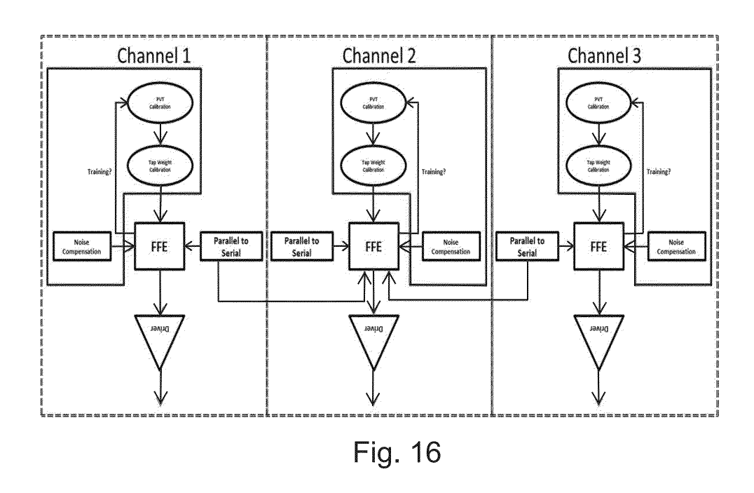

FIG. 16 illustrates compensation and data flow for several channels using a voltage mode driver of the present invention. Tx operation is divided into two phases, a first phase for training/calculation/calibration and a second phase for normal operation. During the first phase, a driver can be calibrated for desired output impedance. This will determine the maximum number legs that should be enabled to get a desired impedance; in this case 50 ohms, which is equal to a total weight of 1. Next, the driver calibrates/calculates/trains different tap weights. Once the PVT legs and tap weight in terms of legs are determined, this will be fed to the FFE along with the noise compensation information. During the second phase (or normal operation), the FFE reads PVT compensation information, tap weights, and noise compensation to apply these information to serial data, before being inputted to the final driver.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

We claim:

1. A differential mode driver for driving a differential signal, comprising,
at least one unit cell, wherein each of the at least one unit cell comprises at least one resistor and at least one switch resistance and wherein the ratio of the resistances of the at least one resistor and the at least one switch resistance is greater than or equal to a predefined ratio.
